(19) United States
(12) Patent Application Publication
(10) Pub. No.: US 2009/0155717 A1
(43) Pub. Date: Jun. 18, 2009

(54) Photosensitive Resin Composition with Good Stripper-Resistance for Color Filter and Color Filter Formed Using the Same

(75) Inventors: Sang-Won CHO, Uiwang-si (KR); Gyu-Seok HAN, Uiwang-si (KR); Ho-Jeong PAEK, Uiwang-si (KR); Myung-Jin LEE, Uiwang-si (KR); Sun-Hee JIN, Uiwang-si (KR); Cheon-Seok LEE, Uiwang-si (KR)

Correspondence Address: SUMMA, ADDITON & ASHE, P.A., 11610 NORTH COMMUNITY HOUSE ROAD, SUITE 200, CHARLOTTE, NC, 28277, US

(73) Assignee: CHEIL INDUSTRIES INC., Gumi-si (KR)

(21) Appl. No.: 12/337,743

(22) Filed: Dec. 18, 2008

(30) Foreign Application Priority Data
Dec. 18, 2007 (KR) 10-2007-0133812
Dec. 17, 2008 (KR) 10-2008-0128853

(51) Int. Cl. G03F 7/028

(52) U.S. Cl. 430/280.1; 430/285.1

(57) ABSTRACT

The present invention relates to a photosensitive resin composition for a color filter, which has an excellent stripper-resistance and is developed by an alkali aqueous solution, and a color filter formed of the photosensitive resin composition. The photosensitive resin composition includes: (A) a carboxyl-containing acryl-based binder resin; (B) a double bond-containing acryl carboxylate resin represented by the following Formula 1; (C) an acryl-based photopolymerization monomer; (D) a photopolymerization initiator; (E) a pigment; and (F) a solvent. The photosensitive resin composition has excellent stripper resistance, and thus can be used when a color filter is fabricated on a TFT array substrate in order to ensure a high aperture ratio.

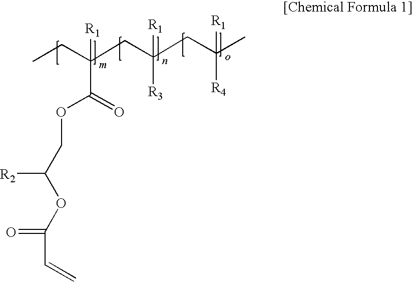

In the above formula, R₁ is hydrogen or methyl, R₂ is hydrogen, hydroxyl, C1 to C10 alkyl, or —CO—R₅—COOH wherein R₅ is a moiety derived from an acid anhydride, R₃ is R₆COO— wherein R₆ is aryl, R₄ is R₇COO— wherein R₇ is alkyl, 5≦m≦50, 1≦n≦20, and 10≦o≦100.

### CROSS-REFERENCE TO RELATED APPLICATION

This application claims priority to and the benefit of Korean Patent Application No. 10-2007-0133812 filed in the Korean Intellectual Property Office on Dec. 18, 2007, and of Korean Patent Application No. 10-2008-0128853 filed in the Korean Intellectual Property Office on Dec. 17, 2008, the entire disclosure of each of which is incorporated herein by reference.

### FIELD OF THE INVENTION

The present invention relates to a photosensitive resin composition having excellent stripper-resistance and a color filter using the same.

### BACKGROUND OF THE INVENTION

Color filters are used in liquid crystal displays (LCD), optical filters for cameras, and the like. Color filters can be fabricated by coating a fine region colored with three or more colors on a charge coupled device or a transparent substrate. Dyeing, printing, electrophoretic deposition (EPD), pigment dispersion, and the like are examples of techniques for fabricating a colored thin film.

Dyeing forms a colored film by forming an image with a dyeing agent on a substrate and then dyeing the image with direct dyes. Examples of dyeing agents useful in the fabrication of colored thin films include natural photosensitive resins such as gelatin and the like, amine-modified polyvinyl alcohols, amine-modified acryl-based resins, and the like. However, the dyeing process may be complex and lengthy, since it should include resist printing whenever a color needs to be changed to form a multicolored thin film on the same substrate. In addition, many generally-used dyes and resins may have good color vividness and dispersion but also poor light fastness, water resistance, and heat resistance, which are very important characteristics. For example, Korean Patent Laid-Open Publication No. 1991-4717 and No. 1994-7778 include azo and azide compounds as a dye, which have deteriorated heat resistance and durability compared to a pigment.

Printing forms a colored thin film by printing an ink prepared by dispersing a pigment into a thermally curable or photocurable resin and curing it with heat or light. This method may decrease material costs compared with other methods, but it can be difficult to form a fine and precise image and acquire a uniform thin film layer using printing techniques. Korean Patent Laid-Open Publication No. 1995-7003746 discloses a method of making a color filter using an ink jet method. However, the resultant color filter suffers similar problems as color filters made using dyeing techniques, such as deteriorated durability and heat resistance, because the ink jet printing method also uses a dye-type color resist composition dispersed from a nozzle to accomplish fine and precise color printing.

Korean Patent Laid-Open Publication No. 1993-7000858 and 1996-29904 disclose electrophoretic deposition (EPD) using an electric precipitation method. The electrophoretic deposition (EPD) can form a precise color film having excellent heat resistance and light fastness, since it includes a pigment. However, when a finer electrode pattern is needed for a more sophisticated pixel in the future, it can be difficult to use this method to make a color filter requiring a high level of sophistication because the colored film may be stained or thicker at both ends due to electrical resistance.

Pigment dispersion forms a colored film by repeating a series of processes such as coating, exposing to light, developing, and curing a photopolymer composition including a coloring agent on a transparent substrate including a black matrix. Pigment dispersion can improve heat resistance and durability, which are very important characteristics of a color filter, and can provide a uniform film thickness. As examples, Korean Patent Laid-Open Publication Nos. 1992-7002502 and 1995-7000359 and Korean patent publication Nos. 1994-5617 and 1995-11163 disclose methods of making a color resist using pigment dispersion methods.

When a photosensitive resin composition for a color filter is prepared using a pigment dispersion method, the composition generally includes a binder resin, a photopolymerization monomer, a photopolymerization initiator, an epoxy resin, a solvent, and other additives. For example, the binder resin can include a carboxyl-containing acryl-based copolymer as in Japanese Patent Laid-Open Publication Nos. Pyung 7-140654 and 10-254133.

The color filter is subjected to many chemical treatments during the manufacturing process. Accordingly, a color photosensitive resin is required to have a development margin and chemical resistance such that it can accomplish yield improvement of a color filter in order to maintain a pattern formed under the aforementioned conditions.

For example, a color filter substrate for displaying a color image in a conventional color liquid crystal display (LCD) and an operating substrate on which a thin film transistor (TFT) is disposed are fabricated in separate steps, and then the color filter substrate and the operating substrate with the TFTs disposed thereon are bound together. However, methods for binding the color filter substrate and the operating substrate can have low arrangement accuracy during the binding, and thus such methods can require a shading layer with a large width. Accordingly, it is difficult to increase aperture ratio (a ratio of active light-emitting area to total pixel area). In addition, as the glass substrate and LCD screen of liquid crystal displays (LCD) increase in size, the substrate needs a larger area for vacuum implanting the liquid crystal after the binding. It also takes a longer time for the liquid crystal composition to evenly spread over the substrates. A method has been suggested to sharply decrease the time needed for printing a seal material and dripping a liquid crystal for over-coating, but it has an arrangement problem that sharply deteriorates arrangement accuracy.

As an alternative, a method of forming a color filter on the operating TFT array substrate of a TFT color liquid crystal display (LCD) has been suggested. Since a color filter substrate is unnecessary, this method has an advantage of simple arrangement and an increased aspect rate by binding two substrates after fabricating a transparent substrate through sputtering.

When a color filter is formed on a TFT array substrate, a pixel electrode is formed on the color filter in a photolithography method using a common positive photoresist. Accordingly, the resist layer needs to be removed after forming the electrode. In other words, a pixel electrode is formed by forming a transparent electrode layer on color pixels of a color filter, coating a positive resist thereon, and patterning it, exposing it to light, and developing it. Then, the resist layer remaining on the pixel electrode is peeled and removed with a resist stripper. Accordingly, the color filter requires resistance against a positive resist stripper. Conventional photo-curable coloring compositions, however, typically have weak stripper-resistance.

A pixel electrode can be fabricated by forming a pixel protective layer having stripper-resistance on a color filter. In addition, a pixel electrode can be fabricated by using a stripper under milder conditions and peeling a positive resist at a low temperature for a longer time without coating a pixel protective layer. However, these techniques can have problems, such as deteriorating yield rate and production efficiency, since they require more process steps and longer production times.

In order to solve these problems, a radiation-sensitive composition with an expansion rate of less than 5% against the stripper solution can be used to make a curing layer forming a color layer in a color filter on array (COA) method. Further, thermal polymerization cross-linking properties of the color filter can be improved by using a multi-functional alicyclic epoxy compound in a thermal polymerization cross-linking agent and a benzophenone-based peroxide as a photo-thermal polymerization initiator. In this method, a color filter can be cured at a low temperature and for a short time, and can thereby have excellent durability and close contacting (adhesion) properties. However, a color filter with a higher aperture ratio and higher performance is required as demand increases for larger screens with higher image quality than those produced using conventional techniques.

### SUMMARY OF THE INVENTION

An exemplary embodiment of the present invention provides a photosensitive resin composition useful for the production of a color filter. The photosensitive resin composition of the invention can be alkali aqueous solution developable. The photosensitive resin composition can be particularly useful for the production of a color filter on a TFT array substrate because the composition can have excellent close contacting (adhesion) properties with a lower layer and excellent resistance against a resist stripper such as that used to fabricate a pixel electrode. The photosensitive resin composition can accordingly also provide a high aperture ratio to the resultant device.

Another embodiment of the present invention provides a high quality color filter prepared by using the photosensitive resin composition, which can include a color filter formed on a TFT array substrate. Yet another embodiment of the present invention provides a device including a color filter prepared using the photosensitive resin composition, including devices in which the color filter is formed on a TFT array substrate. Other embodiments of the invention include methods of forming a color filter using the photosensitive resin composition, including methods for forming a color filter on a TFT array substrate, and methods of forming a device including a color filter using the photosensitive resin composition, including devices in which the color filter is formed on a TFT array substrate

The embodiments of the present invention are not limited to the above technical purposes, and a person of ordinary skill in the art can understand other technical purposes.

According to one embodiment of the present invention, a photosensitive resin composition for a color filter is provided, including: (A) a carboxyl-containing acryl-based binder resin; (B) a double bond-containing acryl carboxylate resin represented by the following Formula 1; (C) an acryl-based photopolymerization monomer; (D) a photopolymerization initiator; (E) a pigment; and (F) a solvent.

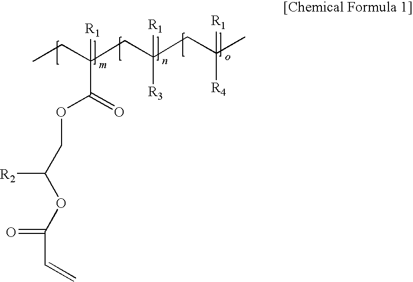

In the above formula, each R₁ is independently hydrogen or methyl, R₂ is hydrogen, hydroxyl, C1 to C10 alkyl, or —CO—R₅—COOH wherein R₅ is a moiety derived from an acid anhydride, R₃ is R₆COO— wherein R₆ is aryl, R₄ is R₇COO— wherein R₇ is alkyl, 5≦m≦50, 1≦n≦20, and 10≦o≦100.

According to another embodiment of the present invention, provided is a color filter fabricated by forming patterns with the photosensitive resin composition.

Hereinafter, embodiments of the present invention will be described in detail.

Since the photosensitive resin composition has excellent stripper-resistance, particularly to a negative resist resin stripper, it can be used to fabricate a color filter on a TFT array substrate to secure a high aperture ratio.

### DETAILED DESCRIPTION OF THE INVENTION

The present invention now will be described more fully hereinafter in the following detailed description of the invention, in which some, but not all embodiments of the invention are described. Indeed, this invention may be embodied in many different forms and should not be construed as limited to the embodiments set forth herein; rather, these embodiments are provided so that this disclosure will satisfy applicable legal requirements.

As used herein, when a specific definition is not otherwise provided, the term “alkyl” refers to a C1-C30 alkyl, the term “aryl” refers to a C6-C30 aryl, and the term “acid anhydride” refers to an acid anhydride derived from a C1-C30 carboxylic acid.

The photosensitive resin composition according to one embodiment of the present invention includes: (A) a carboxyl-containing acryl-based binder resin; (B) a double bond-containing acryl carboxylate resin represented by the above following Formula 1; (C) an acryl-based photopolymerization monomer; (D) a photopolymerization initiator; (E) a pigment; and (F) a solvent.

Hereinafter, the components of the photosensitive resin composition for a color filter according to one embodiment of the present invention are illustrated in detail.

(A) Carboxyl-Containing Acryl-Based Binder Resin

The carboxyl-containing acryl-based binder resin is a copolymer of a first ethylenic unsaturated monomer including at least one carboxyl group and a second ethylenic unsaturated monomer copolymerizable with the first ethylenic unsaturated monomer. The carboxyl-containing acryl-based binder resin includes the first carboxyl-containing ethylenic unsaturated monomer in an amount of about 5 to about 50 wt %, based on the total weight of the monomers of the acryl-based binder resin. In one embodiment, the carboxyl-containing acryl-based binder resin includes the first carboxyl-containing ethylenic unsaturated monomer in an amount of about 10 to about 40 wt %, and in another embodiment, in an amount of about 20 to about 30 wt %.

The carboxyl-containing acryl-based binder resin has a molecular weight (Mw) of about 10,000 to about 70,000. In one embodiment, the carboxyl-containing acryl-based binder resin has a molecular weight of about 20,000 to about 50,000.

The carboxyl-containing acryl-based binder resin also has an acid value of about 25 to about 160 mg KOH/g. In one embodiment the carboxyl-containing acryl-based binder resin has an acid value ranging from about 30 to about 150 mg KOH/g. When the carboxyl-containing acryl-based binder resin has a molecular weight and acid value within the above ranges, the binder resin can provide a resist having excellent developability.

Exemplary first carboxyl-containing ethylenic unsaturated monomers suitable for use in the present invention include, but are not limited to, acrylic acid, methacrylic acid, maleic acid, itaconic acid, fumaric acid, and the like, and combinations thereof. The carboxyl-containing acryl-based binder resin includes the above-described compounds as a first monomer.

Exemplary second ethylenic unsaturated monomers copolymerizable with the carboxyl-containing ethylenic unsaturated monomer suitable for use in the present invention include, but are not limited to: alkenyl aromatic monomers such as styrene, a-methyl styrene, vinyl toluene, vinyl benzyl methyl ether, and the like; unsaturated carbonic acid esters such as methyl acrylate, methyl methacrylate, ethyl acrylate, ethyl methacrylate, butyl acrylate, butyl methacrylate, 2-hydroxy ethyl acrylate, 2-hydroxy ethyl methacrylate, 2-hydroxy butyl acrylate, 2-hydroxy butyl methacrylate, benzyl acrylate, benzyl methacrylate, cyclohexyl acrylate, cyclohexyl methacrylate, phenyl acrylate, phenyl methacrylate, and the like; unsaturated carbonic acid aminoalkyl esters such as 2-amino ethyl acrylate, 2-amino ethyl methacrylate, 2-dimethyl amino ethyl acrylate, 2-dimethyl amino ethyl methacrylate, and the like; carbonic acid vinyl esters such as vinyl acetate, vinyl benzoate, and the like; unsaturated carbonic acid glycidyl esters such as glycidyl acrylate, glycidyl methacrylate, and the like; vinyl cyanide compounds such as acrylonitrile, methacrylonitrile, and the like; and unsaturated amides such as acryl amide, methacryl amide, and the like, and combinations thereof. The carboxyl-containing acryl-based binder resin includes at least one of the above-described compounds as a second monomer.

Specific examples of the carboxyl-containing acryl-based binder resin prepared from the above monomers include, are not limited to, a methacrylic acid/methyl methacrylate copolymer, a methacrylic acid/benzyl methacrylate copolymer, a methacrylic acid/benzyl methacrylate/styrene copolymer, a methacrylic acid/benzyl methacrylate/2-hydroxy ethyl methacrylate copolymer, and a methacrylic acid/benzyl methacrylate/styrene/2-hydroxy ethyl methacrylate copolymer.

A methacrylic acid/benzyl methacrylate copolymer, one of the carboxyl-containing acryl-based binder resins, may provide remarkable development results for a resist depending on acid value and molecular weight. An exemplary carboxyl-containing acryl-based binder resin having desirable development properties is methacrylic acid/benzyl methacrylate in a weight ratio of 25/75 w/w (%), with an acid value ranging from 80 to 120 mg KOH/g, and with a molecular weight ranging from 20,000 to 40,000.

The photosensitive resin composition includes the carboxyl-containing acryl-based binder resin in an amount of about 0.5 to about 20 wt %, based on the total weight of the photosensitive resin composition. When the photosensitive resin composition includes the binder resin in an amount of less than about 0.5 wt %, the resist may not be developed in an alkali development solution. When the photosensitive resin composition includes the binder resin in an amount of more than about 20 wt %, the resist may lack cross-linking, and thereby have increased surface roughness.

(B) Double Bond-Containing Acryl Carboxylate Resin

The double bond-containing acryl carboxylate resin is a copolymer represented by the following Formula 1.

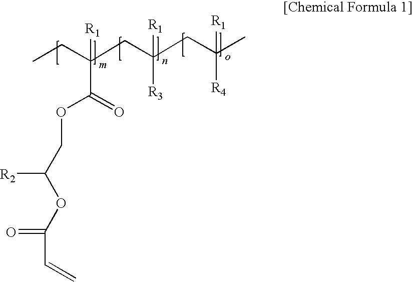

In the above formula, each R₁ is independently hydrogen or methyl, R₂ is hydrogen, hydroxyl, C1 to C10 alkyl, or —CO—R₅—COOH wherein R₅ is a moiety derived from an acid anhydride, R₃ is R₆COO— wherein R₆ is aryl, R₄ is R₇COO— wherein R₇ is alkyl, 5≦m≦50, 1≦n≦20, and 10≦o≦100.

In the above Formula 1, the double bond at a side chain (branch chain) has a similar structure to a photoreaction functional group in a photopolymerization monomer. Since the double bond can form a radical derived by a photopolymerization initiator, it can accordingly contribute to cross-linking of the resin due to a photopolymerization reaction inside the resin.

The double bond-containing acryl carboxylate resin has a molecular weight of about 3000 to about 150,000, and in one embodiment it has a molecular weight of about 5000 to about 50,000. The double bond-containing acryl carboxylate resin has an acid value ranging from about 20 to about 70 mg KOH/g. When the double bond-containing acryl carboxylate resin has a molecular weight and an acid value within this range, a resist can be prepared having excellent development properties.

The degree or amount of photoinitiated cross-linking of the double bond-containing acryl carboxylate resin can be determined by the ratio of photopolymerization monomer and photopolymerization initiator in the resin composition, and can accordingly be controlled by changing their respective ratios.

The photosensitive resin composition may include the double bond-containing acryl carboxylate resin in an amount of about 5 to about 30 wt %, based on the total weight of the photosensitive resin composition. When the photosensitive resin composition includes the double bond-containing acryl carboxylate resin in an amount of less than about 5 wt %, it may have little effect on improvement of chemical resistance. When the photosensitive resin composition includes the double bond-containing acryl carboxylate resin in an amount of more than about 30 wt %, it may have an influence on pattern stability and deteriorate the light transmission characteristic.

(C) Acryl-Based Photopolymerization Monomer

Exemplary acryl-based photopolymerization monomers suitable for use in the present invention include, but are not limited to, ethylene glycol diacrylate, triethylene glycol diacrylate, 1,4-butanediol diacrylate, 1,6-hexanediol diacrylate, neopentyl glycol diacrylate, pentaerythritol diacrylate, pentaerythritol triacrylate, dipentaerythritol diacrylate, dipentaerythritol triacrylate, dipentaerythritol pentaacrylate, pentaerythritol hexaacrylate, bisphenol A diacrylate, trimethylolpropane triacrylate, novolac epoxy acrylate, ethylene glycol dimethacrylate, diethylene glycol dimethacrylate, triethylene glycol dimethacrylate, propylene glycol dimethacrylate, 1,4-butanediol dimethacrylate, 1,6-hexanediol dimethacrylate, and the like, and combinations thereof.

The photosensitive resin composition may include the acryl-based photopolymerization monomer in an amount of about 0.5 to about 20 wt %, based on the total weight of the photosensitive resin composition. When the photosensitive resin composition includes the acryl-based photopolymerization monomer in an amount of less than about 0.5 wt %, the acryl-based photopolymerization monomer may not contribute to the formation of a clear pattern edge. When the photosensitive resin composition includes the acryl-based photopolymerization monomer in an amount of more than about 20 wt %, a resist may not be developed in an alkali development solution.

(D) Photopolymerization Initiator

Exemplary photopolymerization initiators suitable for use in the present invention include, but are not limited to, triazine-based compounds, acetophenone-based compounds, benzophenone-based compounds, thioxanthone-based compounds, benzoin-based compounds, oxime-based compounds, and the like, and combinations thereof.

Exemplary triazine-based compounds include without limitation 2,4,6-trichloro-s-triazine, 2-phenyl-4, 6-bis(trichloro methyl)-s-triazine, 2-(3′,4′-dimethoxy styryl)-4,6-bis( trichloro methyl)-s-triazine, 2-(4′-methoxy naphthyl)-4,6-bis(trichloro methyl)-s-triazine, 2-(p-methoxy phenyl)-4,6-bis(trichloro methyl)-s-triazine, 2-(p-tolyl)-4,6-bis(trichloro methyl)-s-triazine, 2-biphenyl-4,6-bis(trichloro methyl)-s-triazine, bis(trichloro methyl)-6-styryl-s-triazine, 2-(naphto 1-yl)-4,6-bis(trichloro methyl)-s-triazine, 2-(4-methoxy naphto 1-yl)-4,6-bis(trichloro methyl)-s-triazine, 2,4-trichloro methyl(piperonyl)-6-triazine, 2,4-(trichloro methyl(4′-methoxy styryl)-6-triazine, and the like, and combinations thereof.

Exemplary acetophenone-based compounds include without limitation 2,2′-diethoxy acetophenone, 2,2′-dibutoxy acetophenone, 2-hydroxy-2-methyl propiophenone, p-t-butyltrichloro acetophenone, p-t-butyldichloro acetophenone, 4-chloro acetophenone, 2,2′-dichloro-4-phenoxy acetophenone, 2-methyl-1-(4-(methylthio)phenyl)-2-morpholinopropan-1-one, 2-benzyl-2-dimethylamino-1-(4-morpholinophenyl)-butan-1-one, and the like, and combinations thereof.

Exemplary benzophenone-based compounds include without limitation benzophenone, benzoyl benzoate, benzoyl methyl benzoate, 4-phenyl benzophenone, hydroxy benzophenone, acrylated benzophenone, 4,4′-bis(dimethyl amino)benzophenone, 4,4′-bis(diethylamino)benzophenone, 4,4′-dimethylamino benzophenone, 4,4′-dichloro benzophenone, 3,3′-dimethyl-2-methoxy benzophenone, and the like, and combinations thereof.

Exemplary thioxanthone-based compounds include without limitation thioxanthone, 2-methylthioxanthone, isopropyl thioxanthone, 2,4-diethyl thioxanthone, 2,4-diisopropyl thioxanthone, 2-chlorothioxanthone, and the like, and combinations thereof.

Exemplary benzoin-based compounds include without limitation benzoin, benzoin methyl ether, benzoin ethyl ether, benzoin isopropyl ether, benzoin isobutyl ether, benzyldimethylketal, and the like, and combinations thereof.

Exemplary oxime-based compounds include without limitation 2-(o-benzoyloxime)-1-[4-(phenylthio)phenyl]-1,2-octanedione], 1-(o-acetyloxime)-1-[9-ethyl-6-(2-methylbenzoyl)-9H-carbazol-3-yl]ethanone, and the like, and combinations thereof.

The photopolymerization initiator may further include carbazole-based compounds, diketone-based compounds, sulfonium borate-based compounds, diazo-based compounds, biimidazole-based compounds, and the like, and combinations thereof.

The photosensitive resin composition may include the photopolymerization initiator in an amount of about 0.1 to about 10 wt %, based on the total weight of the photosensitive resin composition. When the photosensitive resin composition includes the photopolymerization initiator in an amount of less than about 0.1 wt %, photopolymerization may not be sufficient during exposure in a pattern forming process. When the photosensitive resin composition includes the photopolymerization initiator in an amount of more than about 10 wt %, excess unreacted initiator may remain after the photopolymerization, which may deteriorate transmittance.

(E) Pigment

The pigment can include red, green, blue, yellow, and violet colors. Exemplary pigments suitable for use in the present invention may include without limitation anthraquinone-based pigments, condensation polycyclic pigments such as perylene-based pigments and the like, phthalocyanine pigments, azo-based pigments, and the like. The pigments may be used singularly or in combination of two or more. The combination of two or more pigments can allow adjustment of the maximum absorption wavelength, cross point, crosstalk, and the like.

The pigment can be prepared as a dispersion solution and included in a photosensitive resin composition. The pigment dispersion solution may include ethylene glycol acetate, ethylcellosolve, propylene glycol methyl etheracetate, ethyl lactate, polyethylene glycol, cyclohexanone, propylene glycol methyl ether, and the like, and combinations thereof.

In addition, the pigment may include a dispersing agent to substantially uniformly disperse the pigment. Exemplary dispersing agents suitable for use in the present invention may include all nonionic, negative ionic, or positive ionic dispersing agents, for example polyalkylene glycol and esters thereof, polyoxyalkylene, polyhydric alcohol ester alkylene oxide additives, alcohol alkylene oxide additives, sulfonic acid esters, sulfonic acid salts, carboxylic acid esters, carboxylic acid salts, alkylamide alkylene oxide additives, alkylamines, and the like. These dispersing agents can be used singularly or in combination of two or more.

In addition, a carboxyl-containing acryl-based resin as well as the dispersing agent can be added to the pigment in order to improve stability of a pigment dispersion solution and pixel pattern.

The pigment can have a primary particle diameter ranging from about 10 to about 80 nm. In another embodiment, the pigment can have a primary particle diameter ranging from about 10 to about 70 nm. When the pigment has a primary particle diameter within the above range, it can have excellent stability in a dispersion solution and may not deteriorate pixel resolution.

In addition, the pigment dispersed in a dispersion solution has no particular limit to secondary particle diameter, but may have a secondary particle diameter of less than about 200 nm, depending on the resolution of pixels. In another embodiment, the pigment may have a secondary particle diameter ranging from about 70 to about 100 nm.

The photosensitive resin composition may include the pigment in an amount of about 0.1 to about 40 wt %, based on the total weight of the photosensitive resin composition. When the photosensitive resin composition includes the pigment in an amount of less than about 0.1 wt %, the pigment may have little coloring effects. When the photosensitive resin composition includes the pigment in an amount of more than about 40 wt %, the pigment may sharply deteriorate development performance.

(F) Solvent

Exemplary solvents suitable for use in the present invention include without limitation ethylene glycol acetate, ethyl cellosolve, propylene glycol methyl ether acetate, ethyl ethoxy propionate, ethyl lactate, polyethylene glycol, cyclohexanone, propylene glycol methyl ether, and the like. These solvents may be used singularly or in combination of two or more.

Exemplary solvents include without limitation: ethylene glycols such as ethylene glycol, diethylene glycol, and the like; glycol ethers such as ethylene glycol monomethyl ether, diethylene glycol monomethyl ether, ethylene glycol diethyl ether, diethylene glycol dimethyl ether, and the like; glycol ether acetates such as ethylene glycol monoethyl ether acetate, diethylene glycol monoethyl ether acetate, diethylene glycol monobutyl ether acetate, and the like; propylene glycols such as propylene glycol; propylene glycol ethers such as propylene glycol monomethyl ether, propylene glycol monoethyl ether, propylene glycol monopropyl ether, propylene monobutyl ether, propylene glycol dimethyl ether, dipropylene glycol dimethyl ether, propylene glycol diethyl ether, dipropylene glycol diethyl ether, and the like; propylene glycol ether acetates such as propylene glycol monomethyl etheracetate, dipropylene glycol monoethyl etheracetate, and the like; amides such as N-methyl pyrrolidone, dimethyl formamide, dimethyl acetamide, and the like; ketones such as methylethyl ketone (MEK), methyl isobutyl ketone (MIBK), cyclohexanone, and the like; petroleums such as toluene, xylene, solvent naphtha, and the like; and esters such as ethyl acetate, butyl acetate, ethyl lactate, and the like. These solvents may be used singularly or in combination of two or more.

The solvent may be used as a balance, but in another embodiment, the photosensitive resin composition may include the solvent in an amount ranging from about 20 to about 90 wt %, based on the total weight of the photosensitive resin composition. When the photosensitive resin composition includes the solvent in this range, a photosensitive resin composition may have excellent coating properties and maintain flatness within a 1 μm or thicker layer.

(G) Other Additives

In addition to components (A) to (F), the photosensitive resin composition for a color filter may further include the above-described dispersing agent in order to uniformly disperse the (E) pigment component in the (F) solvent.

The photosensitive resin composition for a color filter may also further include other additives such as but not limited to malonic acid, 3-amino-1,2-propanediol, a vinyl- or (meth)acryloxy-containing silane-based coupling agent, and a fluorine-based surfactant, in order to prevent stains or spots upon coating, to adjust leveling, or to prevent pattern residues due to non-development. These additives may be included in an adjusted amount depending on desired properties.

In addition, a photosensitive resin composition of the present invention may additionally include an epoxy compound to improve adherence and other characteristics if necessary. Exemplary epoxy compounds suitable for use in the present invention may include without limitation epoxy novolac acryl carboxylate resins, ortho cresol novolac epoxy resins, phenol novolac epoxy resins, tetra methyl biphenyl epoxy resins, bisphenol A-type epoxy resins, alicyclic epoxy resins, and the like, and combinations thereof. The photosensitive resin composition may include the epoxy compound in an amount of about 0.01 to about 5 parts by weight, based on the total weight of the photosensitive resin composition. When the photosensitive resin composition includes the epoxy compound in an amount ranging from about 0.01 to about 5 parts by weight, the epoxy compound can improve storage, adherence, and other characteristics.

When the epoxy compound is included, a peroxide initiator or a radical polymerization initiator such as an azobis-based initiator can be additionally included.

According to one embodiment of the present invention, a photosensitive resin composition is coated to a thickness of 3.1 to 3.4 μm on a glass substrate having 500 Å to 1500 Å thick SiNx (protective layer) thereon by a method such as spinning, slitting, and the like. After coating, the photosensitive resin composition is radiated by light to form a pattern required for a color filter. Next, when the coating layer is treated with an alkali development solution to dissolve the non-radiated part, a pattern for a color filter is formed. This process can repeated many times depending on the number of colors of R, G, and B, to provide a color filter with a desired pattern. In this process, the developed image pattern can be heated or cured by actinic rays to improve crack resistance, solvent resistance, and the like.

In general, since a negative photosensitive resin is not easily stripped by an organic solvent, its residue may contaminate a lower layer. In addition, it has a weaker close contacting property (adhesion) to a lower layer than a positive photosensitive resin, which can increase the likelihood of an undercut thereof. The photosensitive resin composition for a color filter of the present invention can exhibit improved stripper resistance and thus reduces the risk of contamination as compared to a negative photosensitive resin and improved adhesion (close contacting property) with a lower layer.

The following examples illustrate the present invention in more detail. However, it is understood that the present invention is not limited by these examples.

### SYNTHESIS EXAMPLE 1

### Synthesis of a Double Bond-Containing Acryl Carboxylate Resin

10 parts by weight of 2,2′-azobis(2,4-dimethylvaleronitrile), 200 parts by weight of propylene glycol monomethyl ether acetate, 15 parts by weight of methacrylic acid, 25 parts by weight of styrene, and 60 parts by weight of hydroxyl-acryloyl ethyloxy methacrylate are put in a flask with a cooler and an agitator under a nitrogen atmosphere, and then slowly agitated. The reaction solution is heated to 80° C. and then maintained for 8 hours, preparing a double bond-containing acryl carboxylate polymer. The polymer solution has a solid concentration of 35 wt %, and the polymer has a weight average molecular weight of 17,000. As used herein, the weight average molecular weight indicates an average molecular weight reduced to polystyrene, measured with GPC.

### EXAMPLE 1

A photosensitive resin composition is prepared by using the following components. First, a photopolymerization initiator is dissolved in a solvent and agitated at room temperature for 2 hours. Next, a carboxyl-containing acryl-based binder resin, a double bond-containing acryl carboxylate resin, and a photopolymerization monomer are added thereto. The resulting mixture is agitated at room temperature for 2 hours. Then, a pigment dispersion solution is added thereto and agitated at room temperature for one hour. Subsequently, a fluorine-based surfactant is added thereto and agitated at room temperature for one hour. The resulting solution is filtered three times to remove impurities.

(A) carboxyl-containing acryl-based binder resin 6.0 g

(a1)/(a2)=25/75 (w/w), molecular weight (Mw)=25,000

(a1): methacrylic acid

(a2): benzyl methacrylate

(B) double bond-containing acryl carboxylate resin

(The polymer prepared in Synthesis Example 1) 3.9 g

molecular weight (Mw)=17,000, acid value=65 mg KOH/g

(C) acryl-based photopolymerization monomer

Dipentaerythritol hexaacrylate (DPHA) 4.1 g

(D) photopolymerization initiator

TPP (Ciba Specialty Chemicals Co.) 0.2 g

(E) pigment dispersion 46.8 g

Red (Ciba Specialty Chemicals Co. BT-CF) (6.2 g)

Yellow (Ciba Specialty Chemicals Co. 2RP-CF) (2.8 g)

Acryl-based dispersing agent (2.4 g)

The above (A) carboxyl-containing acryl binder resin (5.4 g)

Solvent (PGMEA) (30.0 g)

(F) solvent

propylene glycol monomethyl ether acetate 26.0 g

ethyl ethoxy propionate 12.9 g

(G) additive

F-475 (fluorine-based surfactant) 0.1 g

### COMPARATIVE EXAMPLE 1

A photosensitive resin composition is prepared according to the same method as Example 1 except an epoxy acryl carboxylate resin (EOCN, Nippon Kayaku) is used instead of a double bond-containing acryl carboxylate resin.

### COMPARATIVE EXAMPLE 2

A photosensitive resin composition is prepared according to the same method as Example 1 except a double bond-containing acryl carboxylate resin is not used.

The resin compositions according to Example 1 to Comparative Examples 1 to 2 are evaluated for stripper-resistance.

The photosensitive resin compositions of Example 1 to Comparative Examples 1 to 2 are coated to form a layer 3.1 to 3.4 μm thick on a glass plate with a 500 Å SiNx layer using a spin coater. Next, the layer is soft-baked at 80° C. for 150 seconds using a hot plate. Then, the layer is exposed to light of 60 mJ using an exposing device and developed for 60 seconds using a developer, washed for 60 seconds, and spin-dried for 25 seconds. Then development is performed at 25° C. in a 1% potassium hydroxide solution. Then, the layer is hard-baked in a 230° C. oven for 30 minutes. The specimen is measured regarding color change with a calorimeter after the hard-baking as follows.

The hard-baked specimen is dipped in a 70° C. stripper solution (J. T. Baker™ PRS-2000™) for 10 minutes and dried with DIW, and then examined regarding color change and peeling of the color photosensitive resin thereon with a colorimeter and a microscope. The result is categorized as follows.

Color Change

weak color change after stripper treatment: excellent

strong color change after stripper treatment: bad

Peeling

No peeling of a color photosensitive resin: excellent

partial peeling of a color photosensitive resin: bad

The results are provided in the following Table 1.

TABLE 1

| | | | Peeling of | |
|---|---|---|---|---|
| | | | a photosensitive | |
| | Color change | | resin strip | |
| | Bare glass | SiNₓ | Bare glass | SiNₓ |
| Example 1 | Excellent | excellent | excellent | excellent |
| Comparative | Excellent | excellent | insufficient | insufficient |
| Example 1 | | | | |
| Comparative | Excellent | excellent | bad | bad |
| Example 2 | | | | |

As shown in Table 1, a photosensitive resin composition of the present invention has excellent resistance against a stripper.

Many modifications and other embodiments of the invention will come to mind to one skilled in the art to which this invention pertains having the benefit of the teachings presented in the foregoing descriptions. Therefore, it is to be understood that the invention is not to be limited to the specific embodiments disclosed and that modifications and other embodiments are intended to be included within the scope of the appended claims. Although specific terms are employed herein, they are used in a generic and descriptive sense only and not for purposes of limitation, the scope of the invention being defined in the claims.

What is claimed is:

1. A photosensitive resin composition for a color filter, comprising:
(A) a carboxyl-containing acryl-based binder resin;
(B) a double bond-containing acryl carboxylate resin represented by the following Formula 1;
(C) an acryl-based photopolymerization monomer;
(D) a photopolymerization initiator;
(E) a pigment; and
(F) a solvent, 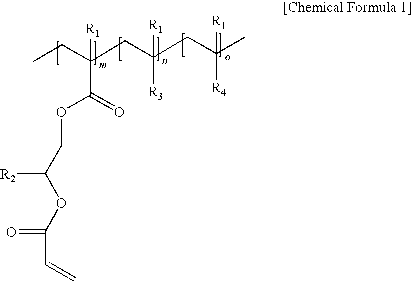
wherein, in the above formula, each R₁ is independently hydrogen or methyl, R₂ is hydrogen, hydroxyl, C1 to C10 alkyl, or —CO—R₅—COOH wherein R₅ is a moiety derived from an acid anhydride, R₃ is R₆COO— wherein R₆ is aryl, R₄ is R₇COO— wherein R₇ is alkyl, 5≦m≦50, 1≦n≦20, and 10≦o≦100.

2. The photosensitive resin composition of claim 1, wherein the photosensitive resin composition comprises about 0.5 to about 20 wt % of the (A) carboxyl-containing acryl-based binder resin, about 0.5 to about 10 wt % of the (B) double bond-containing acryl carboxylate resin, about 0.5 to about 10 wt % of the (C) acryl-based photopolymerization monomer, about 0.1 to about 30 wt % of the (D) photopolymerization initiator, 0.1 to 40 wt % of the (E) pigment, and the balance of the (F) solvent.

3. The photosensitive resin composition of claim 1, wherein the carboxyl-containing acryl-based binder resin is a copolymer of a first ethylenic unsaturated monomer including at least one carboxyl group and a second ethylenic unsaturated monomer that is copolymerizable with the first ethylenic unsaturated monomer.

4. The photosensitive resin composition of claim 1, wherein the carboxyl-containing acryl-based binder resin has a molecular weight (Mw) of about 10,000 to about 70,000.

5. The photosensitive resin composition of claim 1, wherein the double bond-containing acryl carboxylate resin has a molecular weight of about 3000 to about 150,000.

6. The photosensitive resin composition of claim 1, wherein the double bond-containing acryl carboxylate resin has an acid value ranging from about 20 to about 70 mg KOH/g.

7. The photosensitive resin composition of claim 1, wherein the photosensitive resin composition further comprises at least one or more additives selected from dispersing agents; malonic acid; 3-amino-1,2-propanediol; vinyl- or (meth)acryloxy-containing silane-based coupling agents; leveling agents; surfactants; epoxy compounds; or mixtures thereof.

8. A color filter fabricated by using the photosensitive resin composition according to claim 1.

9. A device comprising a color filter fabricated by using the photosensitive resin composition according to claim 1.

10. The device of claim 9, wherein the filter is fabricated on a TFT array substrate.
